(19) United States
(12) Patent Application Publication
(10) Pub. No.: US 2003/0054642 A1
(43) Pub. Date: Mar. 20, 2003

(54) Production method of semiconductor device and production system of semiconductor device

(76) Inventors: Hiroshi Kagotani, Kanagawa (JP); Harunobu Hirano, Nagasaki (JP); Mitsuo Hama, Nagasaki (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/168,590

(22) PCT Filed: Oct. 24, 2001
(86) PCT No.: PCT/JP01/09345

(30) Foreign Application Priority Data
Oct. 25, 2000 (JP) 2000-325172

(51) Int. Cl. H01L 21/302; H01L 21/461

(52) U.S. Cl. 438/689

(57) ABSTRACT

The present invention provides a method of and a system for fabricating a semiconductor device, which are capable of suppressing variations in line widths due to a dependence of a dense/sparse line layout on the line widths within one chip, thereby highly accurately forming micro-patterns on a semiconductor chip or the like. In this method, a numerical aperture of a lens system of an exposure apparatus is adjusted, by a host computer functioning as a numerical aperture adjusting apparatus, so as to reduce variations in line widths of patterns formed in an etching step or resist patterns formed in a photolithography step on the basis of a correlation between the variations in line widths and a dense/sparse line layout for the patterns or a correlation between the variations in line widths and a dense/sparse line layout for the resist patterns.

### TECHNICAL FIELD

The present invention relates to a method of and a system for fabricating a semiconductor device.

### BACKGROUND ART

In recent years, fabrication processes for semiconductor devices such as a semiconductor integrated circuit have been required to more finely form micro-patterns having sizes of a level, for example, 0.25 μm or less. Along with such a tendency to more finely form micro-patterns on a semiconductor chip, it has become more difficult to control variations in line widths as a process factor and errors thereof. In particular, line widths of patterns formed on a semiconductor chip tend to be varied depending on a dense/sparse layout of the patterns, that is, a difference in density between the patterns.

It is important to suppress variations in gate lengths on each semiconductor chip, which are a factor exerting an effect on main device characteristics such as an operational (computing) speed, particularly, of a logic device, and to further improve the accuracy of the gate lengths. Along with a tendency to further improve operational speeds of logic devices and to more finely form patterns on semiconductor chips, it becomes increasingly important to more strictly improve the accuracy of gate lengths on each semiconductor chip by suppressing variations in gate lengths.

In this regard, however, according to related art fabrication methods, since the accuracy of patterns is controlled for each fabrication step, there arises a problem that it is difficult to more accurately suppress the above-described variations in gate lengths on each semiconductor chip.

In particular, for semiconductor chips of a type including a memory device and a logic device combined thereon, circuit patterns very different from each other in arrangement density from a design requirement must be combined within the same chip at a high density and at a high accuracy. The formation of patterns very different in arrangement density within the same chip requires a high-degree process technique, more specifically, a tuning technique capable of highly strictly setting process conditions. According to related art fabrication methods, however, since control of the accuracy of line widths is carried out for each line width, there arises a problem that it is very difficult to realize such very high pattern accuracy.

To suppress occurrence of variations in line widths depending on a dense/sparse line layout, there has been proposed a so-called OPC (Optical Proximity Correction) method. According to this OPC method, a data base is previously formed by assuming a dependence of a dense/sparse line layout on final line widths, for example, on the basis of an exposure accuracy in a photolithography step and an etching factor in a dry etching step, and each line-and-space (combination of a line width and an interval) of a mask pattern or the like is corrected in a photomask producing step by adding the above dependence of a dense/sparse line layout on each target line width. Such a preassumed dependence of a dense/sparse line layout on line widths, however, does not necessarily correspond to a dependence of a dense/sparse line layout on line widths, which is actually caused during a process for fabricating product lots, with a result that a mask pattern may be not sufficiently corrected or the variations in line widths be rather significantly increased. Also it is difficult to perform fine adjustment at a level of less than a minimum correction grid determined by design of a mask pattern. According to the OPC method, if line widths become finer and the accuracy of the line widths becomes stricter, it may be more difficult to suppress variations in line widths. Additionally, according to this method, there may occur an inconvenience that a mask pattern be not sufficiently corrected due to variations in factors during actual fabrication process, for example, a variation in operational condition at the time of transfer of patterns by using a photo-mask, a difference between one and another apparatus of the same kind used as an exposure apparatus or a dry etching apparatus, and a change in process condition set for each apparatus with elapsed time.

In view of the foregoing, the present invention has been made, and an object of the present invention is to provide a method of and a system for fabricating a semiconductor device, which are capable of suppressing variations in line widths due to a dependence of a dense/sparse line layout on the line widths within one chip, thereby highly accurately forming micro-patterns on a semiconductor chip or the like.

### DISCLOSURE OF THE INVENTION

To achieve the above object of the present invention, according to the present invention, there is provided a method of fabricating a semiconductor device, comprising: a plurality of steps of forming patterns on a wafer by adjusting processing conditions; wherein the processing condition of a specific one of the plurality of steps is adjusted so as to reduce variations in line widths of the patterns formed in the plurality of steps on the basis of a correlation between the variations in line widths and a dense/sparse line layout for the patterns.

According to the present invention, there is provided another method of fabricating a semiconductor device, comprising: a photolithography step of transferring a mask pattern to a photoresist on a wafer by adjusting a numerical aperture of an optical system of an exposure apparatus, to form resist patterns; and a patterning step of forming patterns on the wafer on the basis of the resist patterns; wherein the numerical aperture of the optical system is adjusted so as to reduce variations in line widths of the patterns formed in the patterning step or variations in line widths of the resist patterns formed in the photolithography step on the basis of a correlation between the variations in line widths and a dense/sparse line layout for the patterns or a correlation between the variations in line widths and a dense/sparse line layout for the resist patterns.

According to the present invention, there is provided a still another method of fabricating a semiconductor device, comprising: a prebake step of coating a photoresist on a wafer and pre-baking the photoresist while adjusting a prebake temperature; and a photolithography step of transferring a mask pattern to the photoresist, to form resist patterns; wherein the prebake temperature is adjusted so as to reduce variations in line widths of the resist patterns formed in the photolithography step on the basis of a correlation between the variations in line widths and a dense/sparse line layout for the resist patterns.

According to the present invention, there is provided a further method of fabricating a semiconductor device, comprising: a postbake step of post-baking resist patterns, which have been formed on a wafer by processing a photoresist, while adjusting a postbake temperature; and a patterning step of forming patterns on the wafer on the basis of the resist patterns; wherein the postbake temperature is adjusted so as to reduce variations in line widths of the resist patterns on the basis of a correlation between the variations in line widths and a dense/sparse line layout for the patterns formed in the patterning step.

According to the present invention, there is provided a system for fabricating a semiconductor device, which is used for carrying out a plurality of steps of forming patterns on a wafer by adjusting processing conditions, the system comprising: means for adjusting the processing condition of a specific one of the plurality of steps so as to reduce variations in line widths of the patterns formed in the plurality of steps on the basis of a correlation between the variations in line widths and a dense/sparse line layout for the patterns.

According to the present invention, there is provided another system for fabricating a semiconductor device, comprising: a photolithography apparatus for transferring a mask pattern to a photoresist on a wafer by adjusting a numerical aperture of an optical system of an exposure apparatus, to form resist patterns; a patterning apparatus for forming patterns on the wafer on the basis of the resist patterns; and a numerical aperture adjusting apparatus for adjusting the numerical aperture of the optical system so as to reduce variations in line widths of the patterns formed by the patterning apparatus or variations in line widths of the resist patterns formed by the photolithography apparatus on the basis of a correlation between the variations in line widths and a dense/sparse line layout for the patterns or a correlation between the variations in line widths and a dense/sparse line layout for the resist patterns.

According to the present invention, there is provided a still another system for fabricating a semiconductor device, comprising: a pre-baking apparatus for pre-baking a photoresist on a wafer while adjusting a prebake temperature; a photolithography apparatus of transferring a mask pattern to the photoresist, to form resist patterns; and a prebake temperature adjusting apparatus for adjusting the prebake temperature so as to reduce variations in line widths of the resist patterns formed by the photolithography apparatus on the basis of a correlation between the variations in line widths and a dense/sparse line layout for the resist patterns.

According to the present invention, there is provided a further system for fabricating a semiconductor device, comprising: a post-baking apparatus for post-baking resist patterns, which have been formed on a wafer by processing a photoresist, while adjusting a postbake temperature; a patterning apparatus for forming patterns on the wafer on the basis of the resist patterns; and a postbake temperature adjusting apparatus for adjusting the postbake temperature so as to reduce variations in line widths of the resist patterns on the basis of a correlation between the variations in line widths and a dense/sparse line layout for the patterns formed by the patterning apparatus.

With the configurations of the method of or system for fabricating a semiconductor device according to the present invention, variations in line widths of patterns formed by a plurality of steps are reduced by adjusting a processing condition of a specific one of the plurality of steps on the basis of a correlation between the variations in line widths and a dense/sparse line layout for the patterns.

With the configurations of the method of or system for fabricating a semiconductor device according to the present invention, variations in line widths of patterns formed in the patterning step or variations in line widths of resist patterns formed in the photolithography step are reduced by adjusting the numerical aperture of an optical system on the basis of a correlation between the variations in line widths and a dense/sparse line layout for the patterns or a correlation between the variations in line widths and a dense/sparse line layout for the resist patterns.

With the configurations of the method of or system for fabricating a semiconductor device according to the present invention, variations in line widths of resist patterns formed in the photolithography step are reduced by adjusting the prebake temperature in the prebake step or a prebake apparatus on the basis of a correlation between the variations in line widths and a dense/sparse line layout for the resist patterns.

With the configurations of the method of or the system for fabricating a semiconductor device according to the present invention, variations in line widths of resist patterns formed in the postbake step are reduced by adjusting the postbake temperature in the postbake step or a postbake apparatus on the basis of a correlation between the variations in line widths and a dense/sparse line layout for the patterns formed in the patterning step.

Other and further objects, features and advantages of the invention will appear more fully from the following description.

### BRIEF DESCRIPTION OF THE DRAWINGS

FIG. 1 is a schematic diagram showing main fabrication apparatuses of a system for fabricating a semiconductor device according to a first embodiment and the flow of a photolithography step carried out by the main fabrication apparatuses;

FIG. 2 is a schematic diagram showing main fabrication apparatuses of the system for fabricating a semiconductor device according to the first embodiment and the flow of an etching step carried out by the fabrication apparatuses;

FIG. 3 is a flow diagram showing main steps of a procedure for optimizing a numerical aperture of a lens system in a first example;

FIG. 4 is a diagram showing a pattern layout of a chip on which a memory device and a logic device are combined together;

FIG. 5 is a graph showing a correlation between a dense/sparse line width difference and the numerical aperture of a lens system;

FIG. 6 is a graph showing a correlation between the numerical aperture and an optimum exposure amount;

FIG. 7 is a graph showing two curves of variations in line widths depending on a dense/sparse line layout before and after the numerical aperture is corrected and the exposure amount is reset;

FIG. 8 is a schematic diagram showing main fabrication apparatuses of a system for fabricating a semiconductor device according to a second embodiment and the flow of a photolithography step carried out by the fabrication apparatuses;

FIG. 9 is a schematic diagram showing main fabrication apparatuses of the system for fabricating a semiconductor device according to the second embodiment and the flow of an etching step carried out by the fabrication apparatuses;

FIG. 10 is a flow diagram showing main steps of a procedure for optimizing a prebake temperature in a second example;

FIG. 11 is a graph showing a correlation between a dense/sparse line width difference and the prebake temperature;

FIG. 12 is a graph showing a correlation between an optimum exposure amount and the prebake temperature;

FIG. 13 is a graph showing two curves of variations in line widths depending on a dense/sparse line layout before and after the prebake temperature is corrected and the exposure amount is reset;

FIG. 14 is a schematic diagram showing main fabrication apparatuses of a system for fabricating a semiconductor device according to a third embodiment and the flow of a photolithography step carried out by the fabrication apparatuses;

FIG. 15 is a schematic diagram showing main fabrication apparatuses of the system for fabricating a semiconductor device according to the third embodiment and the flow of an etching step carried out by the fabrication apparatuses;

FIG. 16 is a flow diagram showing main steps of a procedure for optimizing a postbake temperature in a third example;

FIG. 17 is a graph showing a correlation between a dense/sparse line width difference and the postbake temperature;

FIG. 18 is a graph showing a correlation between an optimum exposure amount and the postbake temperature; and

FIG. 19 is a graph showing two curves of variations in line width depending on a dense/sparse line layout before and after the postbake temperature is corrected and the exposure amount is reset.

### BEST MODE FOR CARRYING OUT THE INVENTION

Hereinafter, preferred embodiments of the present invention will be described with reference to the drawings.

[First Embodiment]

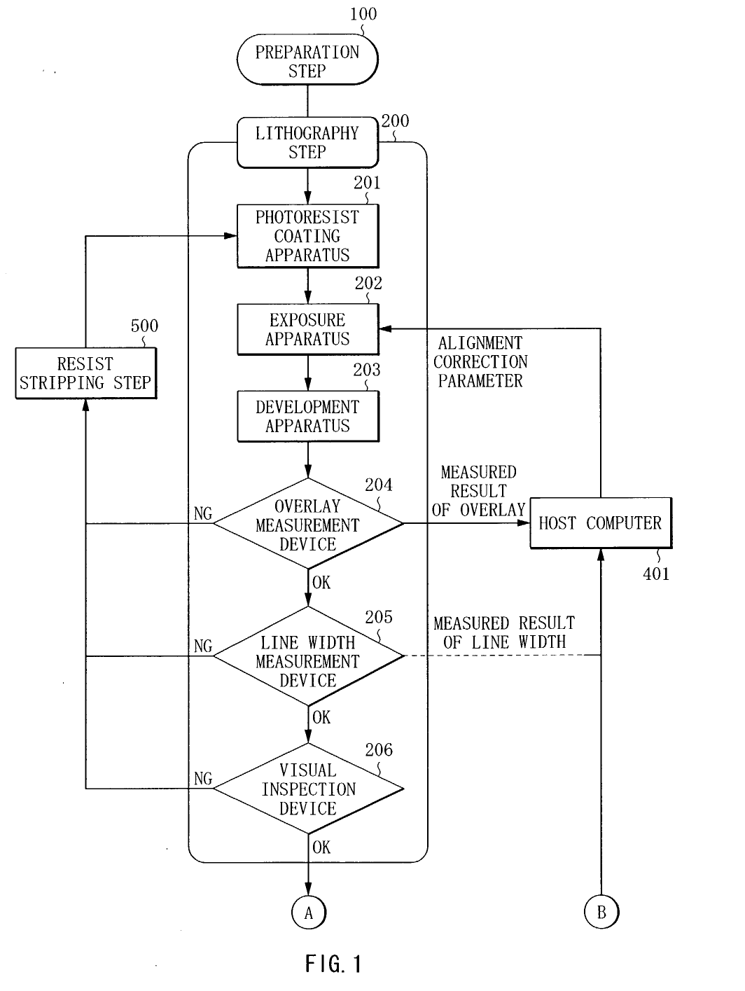

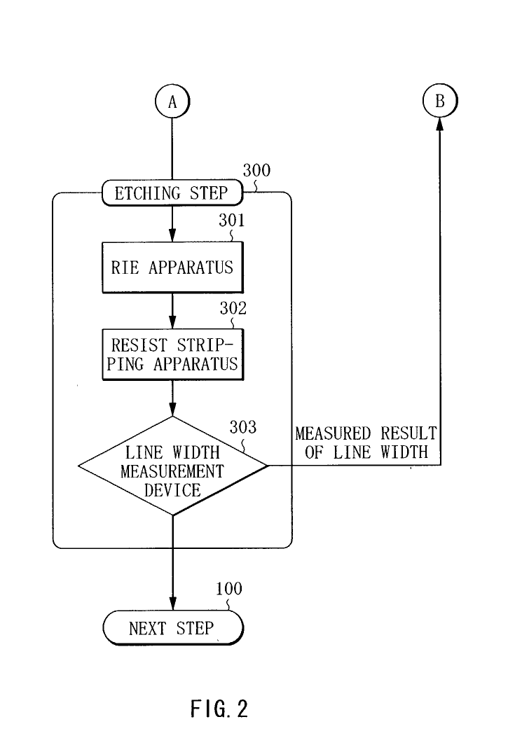

FIGS. 1 and 2 are schematic diagrams showing main fabrication apparatuses of a system for fabricating a semiconductor device according to a first embodiment of the present invention and the flow of fabrication steps carried out by these fabrication apparatuses.

In the first embodiment, the present invention is applied to control of line widths of gate interconnections of a semiconductor device configured as a logic device. It is to be noted that a method of fabricating a semiconductor device according to this embodiment is realized by an operation or a function of the system for fabricating the semiconductor device, and therefore, the fabrication system will be described together with description of the fabrication method.

The system for fabricating a semiconductor device according to this embodiment basically includes three partial subsystems: a sub-system 100 for carrying out a preparation step, a sub-system 200 for carrying out a photolithography step, and a sub-system 300 for carrying out an etching step.

The sub-system 100 for carrying out a preparation step is used to carry out a preparation step including a photo-mask producing step (not shown).

The sub-system 200 for carrying out a photolithography step includes a photoresist coating apparatus 201, an exposure apparatus 202, a development apparatus 203, an overlay measurement device 204, a line width measurement device 205, and a visual inspection device 206. These apparatuses carry out respective general steps, and further, the line width measurement device 205 measures line width differences between densely and sparsely arranged resist patterns and supplies the data to a host computer 401; and the exposure apparatus 202 corrects an NA (Numerical Aperture) of a lens system and resets an optimum exposure condition corresponding to the corrected NA, and thereafter, carries out the exposure step.

The sub-system 300 for carrying out an etching step includes an RIE (Reactive Ion Etching) apparatus 301, a resist stripping apparatus 302, and a line width measurement device 303. These apparatuses carry out general steps, and further, the line width measurement device 303 measures line width differences between densely and sparsely arranged patterns and supplies the data to the host computer 401.

The host computer 401 functions as an NA adjusting apparatus. The host computer 401 calculates a correction value for optimizing the NA of the lens system of the exposure apparatus 202 so as to suppress variations in line widths of the resist patterns or the patterns on the basis of the measured values of the line widths of the resist patterns or the patterns and data of variations in line widths depending on a dense/sparse layout of the resist patterns or the patterns (hereinafter, referred to as “dense/sparse line width difference data”) obtained by the line width measurement device 205 or the line width measurement device 303, and resets an exposure amount in the exposure step, which will be carried out by the exposure apparatus 202 after the present lot, to an optimum value corresponding to the corrected NA.

The exposure apparatus 202 corrects the NA of the lens system on the basis of the corrected NA, which has been calculated by the host computer 401 on the basis of the measured values of the line widths and the dense/sparse line width difference data for the previous lot, and resets an exposure condition such as an exposure amount or an exposure time to that which has been determined in accordance with the corrected NA by the host computer 401. Under such a reset exposure condition, the exposure apparatus 202 will carry out the exposure step for the next lot.

According to a related art method of fabricating a semiconductor device, in a process of forming micro-patterns of a level of, for example, less than 0.25 μm at a required high accuracy, it has failed to eliminate the occurrence of variations in line widths although an optimum processing condition has been set in each of a photolithography step and an etching step, and further it has failed to effectively suppress the variations in line widths even when the processing condition has been corrected for each step.

The present inventors have examined and analyzed the states of occurrence of variations in line widths for actual product lots, and have conducted various experiments, and eventually, the present inventors have found that there is a strong correlation between a dense/sparse layout of patterns and variations in line widths of the patterns. The present inventors have further found that variations in line widths of patterns depending on a dense/sparse layout of the patterns occur depending on a proximity effect in each of a photo-mask producing step, a photolithography step for exposing a photoresist on a wafer to light having passed through a mask pattern to form resist patterns, and an RIE (Reactive Ion Etching) step; and a characteristic error of the photoresist caused in a prebake step for pre-baking a resist film on the wafer or in a PEB (Post Etching Bake; so-called postbake step after exposure).

On the basis of the above knowledge, according to the fabrication method and the fabrication system in the first embodiment, variations in line widths of resist patterns or patterns are suppressed by positively utilizing a function in which the NA of the lens system of the exposure apparatus 202 in the photolithography step exerts an effect on the occurrence of variations in line widths depending on a dense/sparse layout of the transferred resist patterns, or a function in which the NA of the lens system also exerts an effect on the occurrence of variations in line widths depending on a dense/sparse layout of the patterns formed on a wafer by the RIE apparatus 301 in the etching step. To be more specific, dense/sparse line width difference data regarding a correlation between a dense/sparse layout of the resist patterns or the patterns formed on the wafer and variations in line widths of the resist patterns or the patterns, are obtained from data measured by the line width measurement device 205 or the line width measurement device 303. Subsequently, on the basis of the dense/sparse line width difference data, the host computer 401 functioning as the NA adjusting apparatus calculates the optimum NA value of the lens system for effectively suppressing the variations in line widths, calculates a difference between the calculated NA value and a reference NA value (initial value) as a correction value, and corrects the NA of the lens system of the exposure apparatus 202 by using the correction value, whereby the variations in line widths depending on the dense/sparse line width difference are reduced or eliminated.

Variations in line widths depending on a dense/sparse line width difference may be different depending on a photo-mask used; a difference between one and another apparatus of the same kind used as the photoresist coating apparatus 201, the exposure apparatus 202, the development apparatus 203, or the RIE apparatus 301; and further a combination of the apparatuses 201, 202, 203 and 301 in one line. Accordingly, variations in line widths caused in the entire fabrication system can be further reduced by further optimizing the NA of the lens system in consideration of a difference between one and another apparatus and a combination of the apparatuses. For example, the thickness of a photoresist formed by the photoresist coating apparatus and the exposure amount may be adjusted in combination of the correction of the NA, on the basis of the result measured by the overlay measurement device.

Further, in the case where a process parameter or an apparatus parameter is changed due to a modification of a fabrication process, if the change in process parameter or apparatus parameter is small enough not to require the correction of line widths from the time of designing a photo-mask, it is possible to rapidly, certainly optimize the NA and to avoid the increase in cost of the photo-mask by resetting the NA of a lens system in accordance with the change in parameter.

### FIRST EXAMPLE

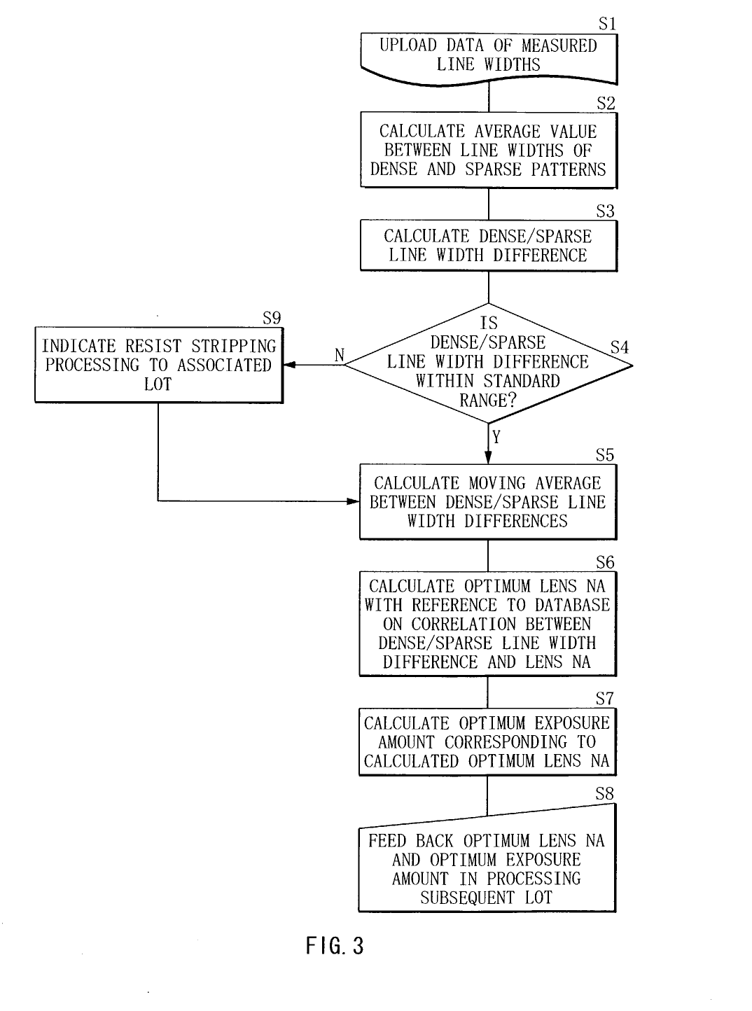

FIG. 3 is a flow diagram of main steps of a procedure for optimizing the NA of the lens system in a first example.

In the first example, a scanner type exposure apparatus including a KrF excimer laser light source (wavelength: 248 nm) was used as the exposure apparatus 202. A PHS (Poly Hydroxy Styrene) based chemically amplified resist (produced by Tokyo Ouka Co., Ltd. under the trade name of TDUR-P509) was used as the photoresist. The photoresist was formed to a thickness of 0.46 μm. In general, the PHS based chemically amplified resist has a strong correlation between variations in line widths depending on a dense/sparse line layout and the NA of the exposure apparatus 202 in the photolithography step. Accordingly, such a chemically amplified resist can be suitably used for the fabrication method in the first example.

Prior to starting of a fabrication process, as representative points at which line widths are to be measured, a plurality of points, each of which has a nearly equal ratio between a line width and an interval (line-and-space), are sampled from a pattern layout of each chip. These representative points are taken as one group, and at least one group is set in each of a sparse pattern region and a dense pattern region.

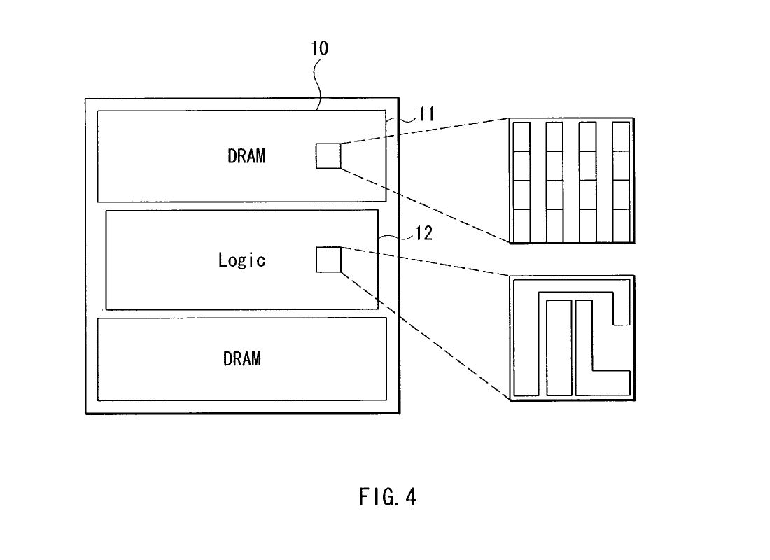

In the first example, each chip has, for example, a pattern layout of a chip 10 shown in FIG. 4 on which a memory device 11 and a logic device 12 are combined. The representative points in the sparse pattern region were sampled from a pattern region of the logic device 12, and the representative points in the dense pattern region were sampled from a pattern region of the memory device 11. It is to be noted that the dense or sparse layout of patterns does not necessarily mean that the density of the patterns is absolutely high or low but means that the density of the patterns is relatively high or low.

First, after a photolithography step or an etching step for one product lot or a trial lot was completed, line widths of the representative points were measured, and the data were supplied to a host computer 401 functioning as an NA adjusting apparatus, to thereby upload the data of the measured line widths (step S1). At this time, an electron microscope with a line width measuring function was used as a line width measurement device 205, and line widths were measured in accordance with a direct approximation method. The measured data were transmitted to the host computer 401 via a CD-SEM, an in-process local network, and the like.

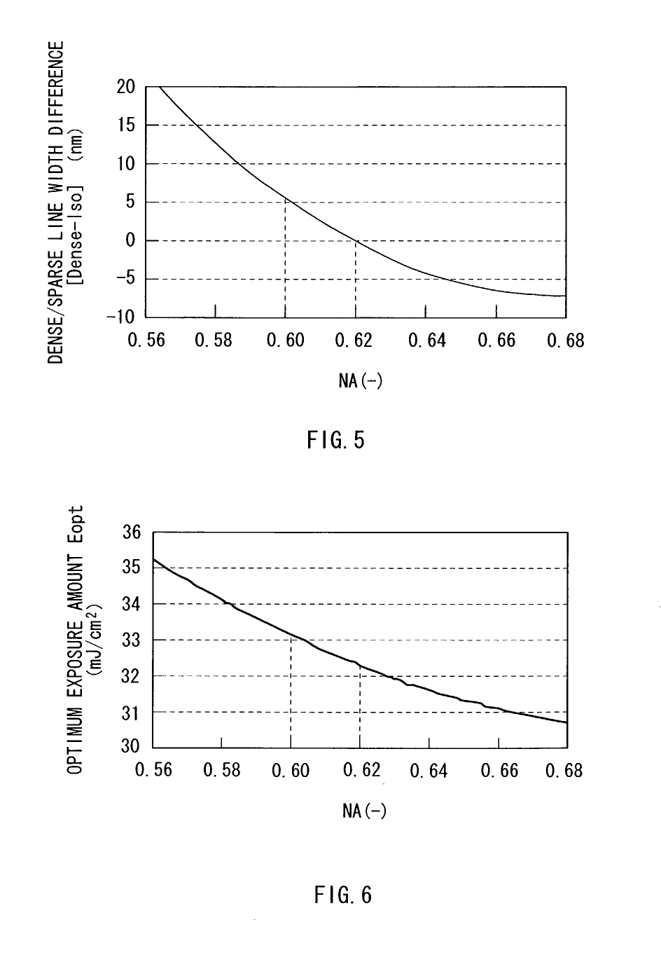

The host computer 401 calculated an average value of the measured line widths in the sparse pattern group and an average value of the measured line widths in the dense pattern group (step S2), and calculated a difference between these two averages (step S3). The value thus obtained in step S3 was taken as a dense/sparse line width difference data. A moving average value between the previous dense/sparse line width difference data, already measured and recorded in the photolithography step or the etching step for a past product lot or trial lot having the same patterns, and the present dense/sparse line width difference data measured for the present lot was calculated (step S5). The data obtained in step S5 were referred to pre-determined correlation data between a dense/sparse line width difference and an NA of a lens system as shown in FIG. 5, and a correction value of the NA selected so as to make the dense/sparse line width difference zero was obtained (step S6). The exposure amount was then reset to an optimum value corresponding to the corrected NA (step S7). The correction value of the NA of the lens system thus calculated and the reset value of the exposure amount were fed back to the exposure apparatus 202 (step S8). In the case of processing wafers of the next lot in the same steps using the same apparatuses, the data of the optimum NA of the lens system thus obtained was transferred from the host computer 401 to the exposure system 202 via the in-process local network or the like, to correct the NA of the lens system and reset the exposure amount.

In the above-described procedure, if the dense/sparse line width difference for the resist patterns is out of a specific range set as a control standard, that is, if the answer of step S4 is denied (NO), the wafer in the lot, on which the resist patterns have been formed, may be removed once from the product line at that time and supplied to a resist stripping (reproducing) step 500, and be coated again with a photoresist and subjected to the subsequent processing in the photolithography step (step S9). With this treatment, if the occurrence of a failure of variations in line widths for a wafer is detected in an early stage in the photolithography step, the wafer is returned to the reproducing step and desirably patterned in the photolithography step which has been corrected to reduce the occurrence of variations in line widths, and accordingly, it is possible to prevent the occurrence of wasteful processing of the wafer and hence to avoid an increase in fabrication cost.

In the first example, the reference NA before correction was initially set to 0.6, and the occurrence of a dense/sparse line width difference of about 5 nm was detected. The NA of the lens system was corrected to 0.62 so as to bring the dense/sparse line width difference into zero on the basis of the correlation between the NA of the lens system and the dense/sparse line width difference shown in FIG. 5.

Along with the correction of the NA of the lens system from 0.60 to 0.62, the optimum exposure amount was shifted to a value different from an optimum exposure amount of 33 mJ/cm² corresponding to the reference NA, that is, the initial value of 0.60. To correct such a shifted value of the optimum exposure amount, on the basis of data of a correlation between the NA and an optimum exposure amount, predetermined on the basis of the data of the past product lots and experiments as shown in FIG. 6, the optimum exposure amount in the exposure apparatus 202 was reset to a value of 32.3 mJ/cm².

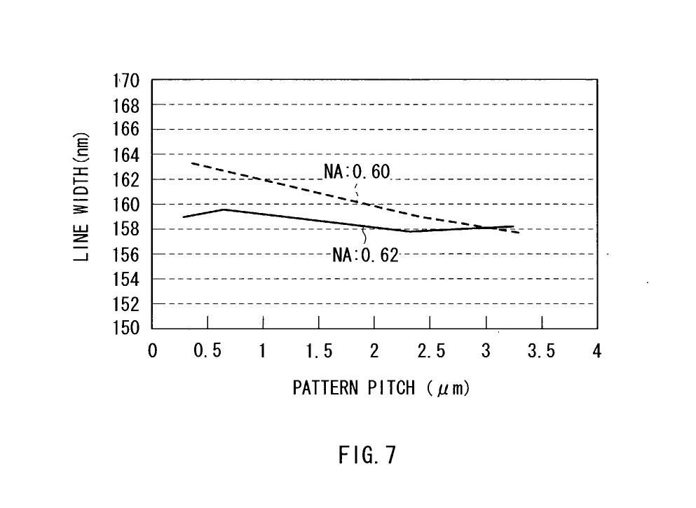

By correcting the NA of the lens system from 0.60 to 0.62 and resetting the optimum exposure amount from 33 mJ/cm² to 32.3 mJ/cm², a dense/sparse line width difference was corrected as shown in FIG. 7. To be more specific, as shown in FIG. 7, in a range of pattern pitches of 0.25 μm to 3.25 μm, the dense/sparse line width difference was corrected from a value of about 5.5 nm at maximum (line width range: 158 nm to 163.5 nm) to a value of less than about 2 nm at maximum (line width range: 157.8 nm to 159.8 nm). In this way, according to the first example, it was found that the variations in line widths can be significantly effectively reduced.

[Second Embodiment]

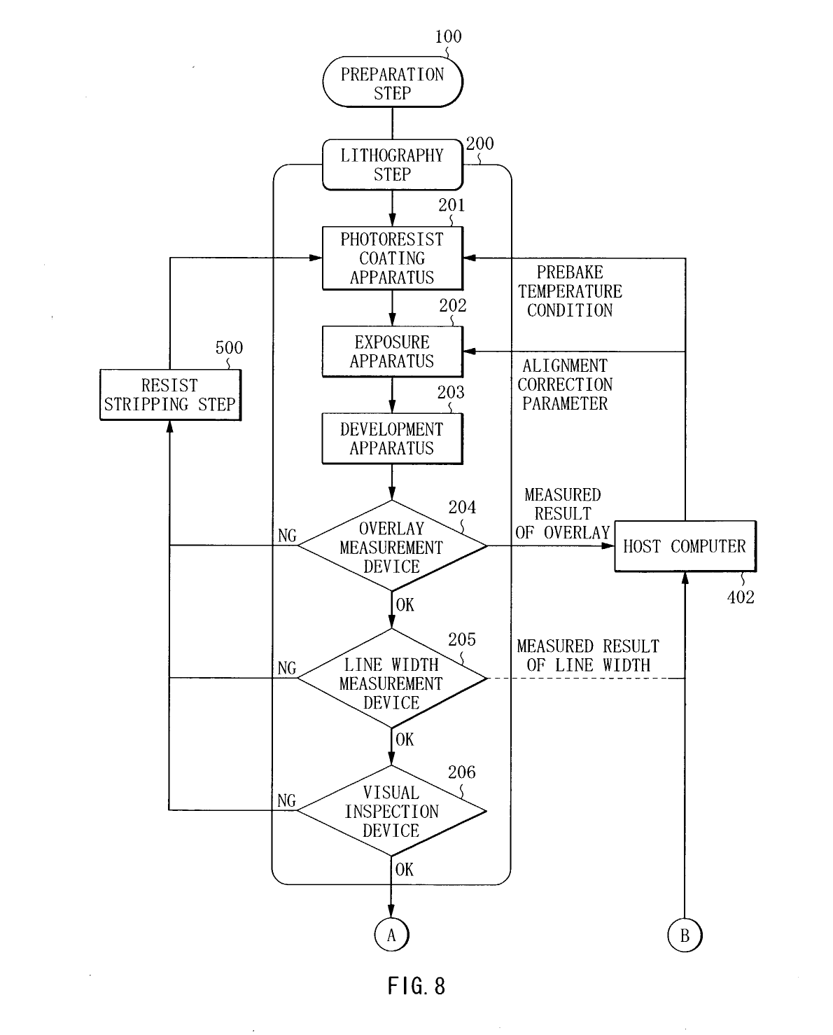

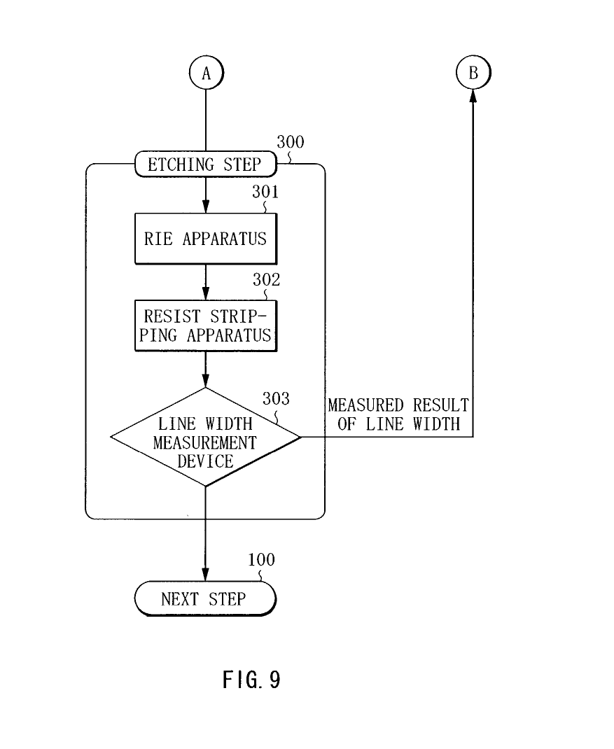

FIGS. 8 and 9 are schematic diagrams showing main fabrication apparatuses of a system for fabricating a semiconductor device according to a second embodiment of the present invention and the flow of fabrication steps carried out by these fabrication apparatuses.

According to the system for fabricating a semiconductor device in this embodiment, a host computer 402 functions as a prebake temperature adjusting apparatus in a prebake step. The host computer 402 calculates dense/sparse line width difference data from values measured by a line width measurement device 205 or a line width measurement device 303, calculates a correction value for optimizing a prebake temperature in the prebake step so as to suppress variations in line widths on the basis of the dense/sparse line width difference data, and resets an exposure amount in an exposure step carried out by an exposure apparatus 202 in the next and later lots to an optimum value.

A photoresist coating apparatus 201 corrects a prebake temperature on the basis of a correction value calculated on the basis of the measured values of the line widths and the dense/sparse line width difference data for the previous lot, and carries out the prebake step at the corrected prebake temperature. The exposure apparatus 202 resets an exposure condition such as an exposure amount or an exposure time on the basis of the corrected prebake temperature. Under such a reset exposure condition, the exposure apparatus 202 will carry out the exposure step for the next lot.

According to the fabrication method and the fabrication system in the second embodiment, variations in line widths of resist patterns or patterns are suppressed by positively utilizing a function in which a prebake temperature in the prebake step exerts an effect on the occurrence of variations in line widths depending on a dense/sparse layout of the transferred resist patterns, or a function in which the prebake temperature in the prebake step also exerts an effect on the occurrence of variations in line widths depending on a dense/sparse layout of the patterns formed on a wafer by the RIE apparatus 301 in the etching step. To be more specific, a dense/sparse line width difference data regarding a correlation between a dense/sparse layout of the resist patterns or the patterns formed on the wafer and variations in line widths of the resist patterns or the patterns, are obtained from data measured by the line width measurement device 205 or the line width measurement device 303. Subsequently, on the basis of the dense/sparse line width difference data, the host computer 402 functioning as the prebake temperature adjusting apparatus calculates the optimum prebake temperature value for effectively suppressing the variations in line widths, calculates a difference between the calculated prebake temperature value and a reference prebake temperature value (initial value) as a correction value, and corrects the prebake temperature by using the correction value, whereby the variations in line widths depending on the dense/sparse line width difference are reduced or eliminated.

Variations in line widths depending on a dense/sparse line width difference may be different depending on a photo-mask used; a difference between one and another apparatus of the same kind used as the photoresist coating apparatus 201, the exposure apparatus 202, the development apparatus 203, or the RIE apparatus 301; and further a combination of the apparatuses 201, 202, 203 and 301 in one line. Accordingly, variations in line widths caused in the entire fabrication system can be further reduced by further optimizing the prebake temperature in consideration of a difference between one and another apparatus and a combination of the apparatuses.

Further, in the case where a process parameter or an apparatus parameter is changed due to a modification of a fabrication process, if the change in process parameter or apparatus parameter is small enough not to require the correction of line widths from the time of designing a photo-mask, it is possible to further reset the prebake temperature in accordance with a change in parameter at that time.

### SECOND EXAMPLE

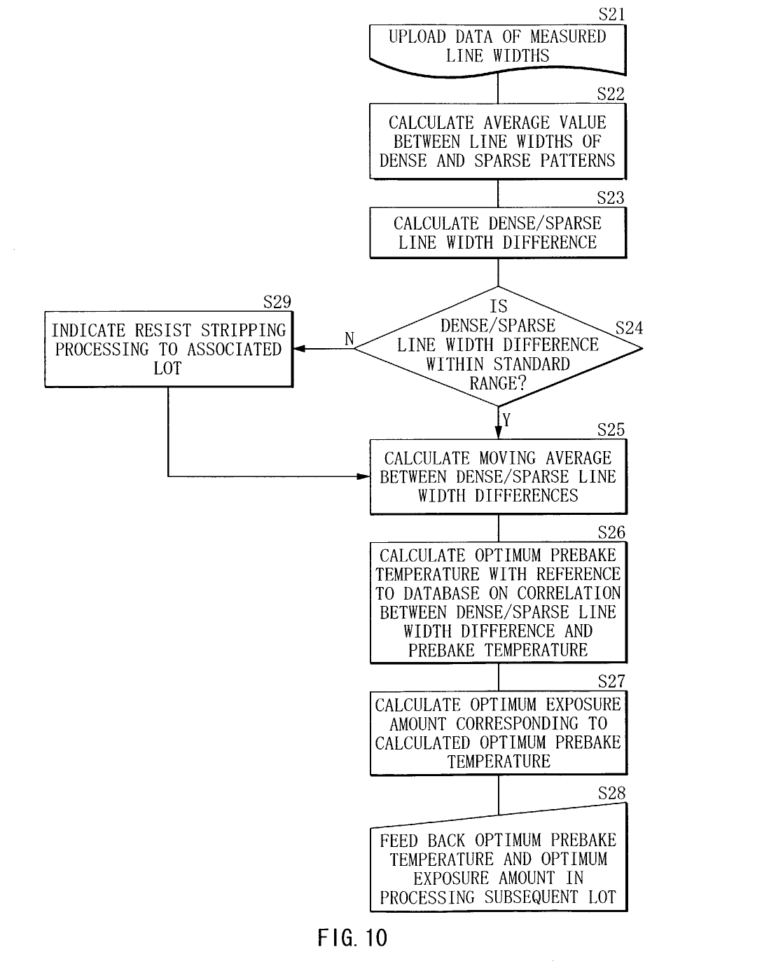

FIG. 10 is a flow diagram of main steps of a procedure for optimizing the prebake temperature in a second example.

In the second example, like the first example, the scanner type exposure apparatus including a KrF excimer laser light source (wavelength: 248 nm) was used as the exposure apparatus 202, and the PHS (Poly Hydroxy Styrene) based chemically amplified resist (produced by Tokyo Ouka Co., Ltd. under the trade name of TDUR-P509) was used as the photoresist. The photoresist was formed to a thickness of 0.46 μm.

Like the first example, in the pattern layout of the chip 10 on which the memory device 11 and the logic device 12 are combined, representative points in a sparse pattern region was sampled from the pattern region of the logic device 12, and representative points in a dense pattern region were sampled from the pattern region of the memory device 11.

First, after a photolithography step or an etching step for one product lot or a trial lot was completed, line widths of the representative points were measured, and the data were supplied to a host computer 402 functioning as a prebake temperature adjusting apparatus, to thereby upload the data of the measured values of line widths (step S21). At this time, like the first example, an electron microscope with a line width measuring function was used as a line width measurement device 205, and line widths were measured in accordance with the direct approximation method. The measured data were transmitted to the host computer 402 via a CD-SEM, an in-process local network, and the like.

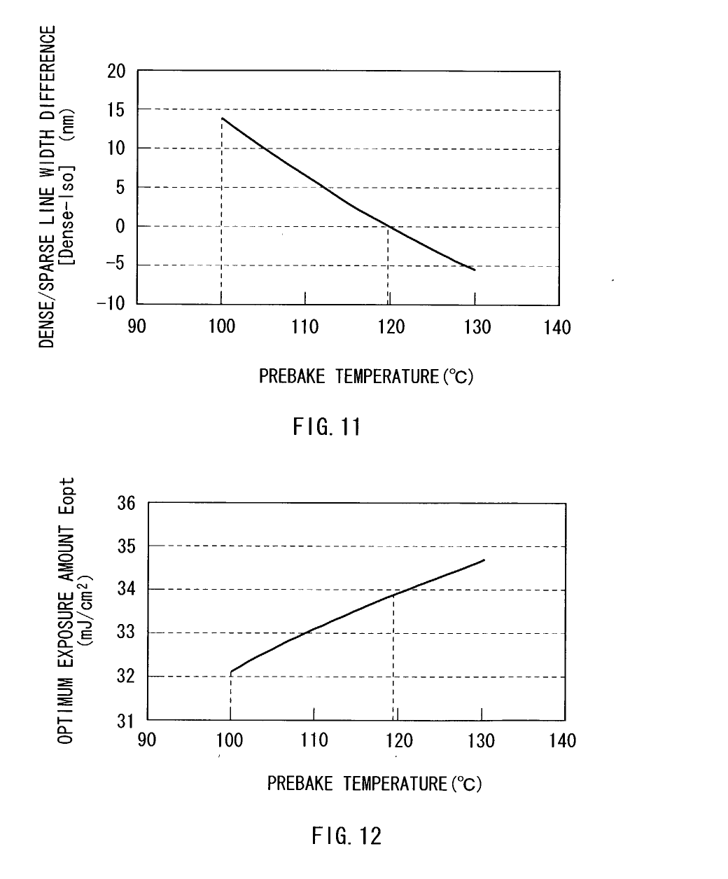

The host computer 402 calculated an average value of the measured line widths in the sparse pattern group and an average value of the measured line widths in the dense pattern group (step S22), and calculated a difference between these two averages (step S23). The value thus obtained in step S23 was taken as a dense/sparse line width difference data. A moving average value between the previous dense/sparse line width difference data, already measured and recorded in the photography step or the etching step for a past product lot or trial lot having the same patterns, and the present dense/sparse line width difference data measured for the present lot was calculated (step S25). The data obtained in step S25 was referred to pre-determined correlation data between a dense/sparse line width difference and a prebake temperature as shown in FIG. 11, and a correction value of the prebake temperature selected so as to bring the dense/sparse line width difference into zero was obtained (step S26). The exposure amount was then reset to an optimum value corresponding to the corrected prebake temperature (step S27). In addition, as typically shown in FIG. 11, a very clear linear correlation is established between the dense/sparse line width difference and the prebake temperature.

The correction value of the prebake temperature thus calculated and the reset value of the exposure amount were fed back to the exposure apparatus 202 (step S28). In the case of processing wafers of the next lot in the same steps using the same apparatuses, the data of the optimum prebake temperature thus obtained were transferred from the host computer 402 to the exposure system 202 via the in-process local network or the like, to correct the prebake temperature and reset the exposure amount.

In the above-described procedure, if the dense/sparse line width difference for the resist patterns is out of a specific range set as a control standard, that is, if the answer of step S24 is denied (NO), the wafer in the lot, on which the resist patterns have been formed, may be removed once from the product line at that time and supplied to a resist stripping (reproducing) step 500, and be coated again with the photoresist and subjected to the subsequent processing in the photolithography step (step S29). With this treatment, if the occurrence of a failure of variations in line widths for a wafer is detected in an early stage in the photolithography step, the wafer is returned to the reproducing step and desirably patterned in the photolithography step which has been corrected to reduce the occurrence of variations in line widths, and accordingly, it is possible to prevent the occurrence of wasteful processing of the wafer and hence to avoid an increase in fabrication cost.

In the second example, the reference prebake temperature before correction was initially set to 100° C., and the occurrence of a dense/sparse line width difference of about 14 nm was detected. The prebake temperature was corrected to 118° C. so as to bring the dense/sparse line width difference into zero on the basis of the correlation between the prebake temperature and the dense/sparse line width difference shown in FIG. 11.

Along with the correction of the prebake temperature from 100° C. to 118° C., the optimum exposure amount was shifted to a value different from an optimum exposure amount of about 32 mJ/cm² corresponding to the reference prebake temperature, that is, the initial value of 100° C. To correct such a shifted value of the optimum exposure amount, on the basis of data of a correlation between the prebake temperature and an optimum exposure amount, predetermined on the basis of the data of the past product lots and experiments as shown in FIG. 12, the optimum exposure amount in the exposure apparatus 202 was reset to a value of 34 mJ/cm².

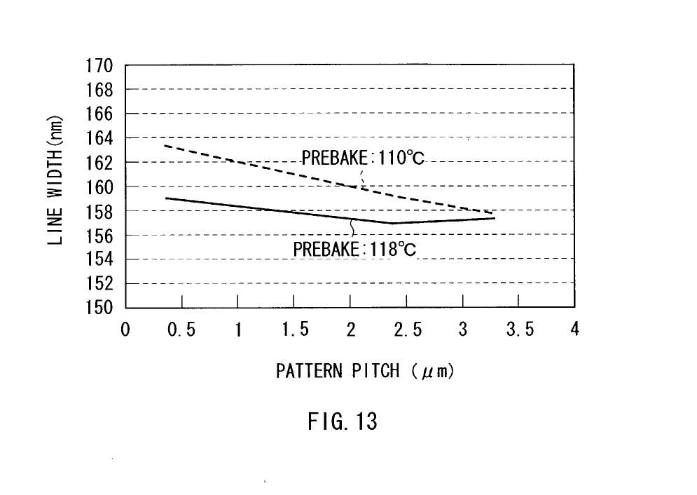

By correcting the prebake temperature from 100° C. to 118° C. and also resetting the optimum exposure amount from 32 mJ/cm² to 34 mJ/cm², a dense/sparse line width difference was corrected as shown in FIG. 13. To be more specific, as shown in FIG. 13, in a range of pattern pitches of 0.25 μm to 3.25 μm, the dense/sparse line width difference was corrected from a value of about 5.5 nm at maximum (line width range: 158 nm to 163.5 nm) to a value of about 2 nm or less at maximum (line width range: 157 nm to 159 nm). In this way, according to the second example, it was found that the variations in line widths could be significantly effectively reduced.

[Third Embodiment]

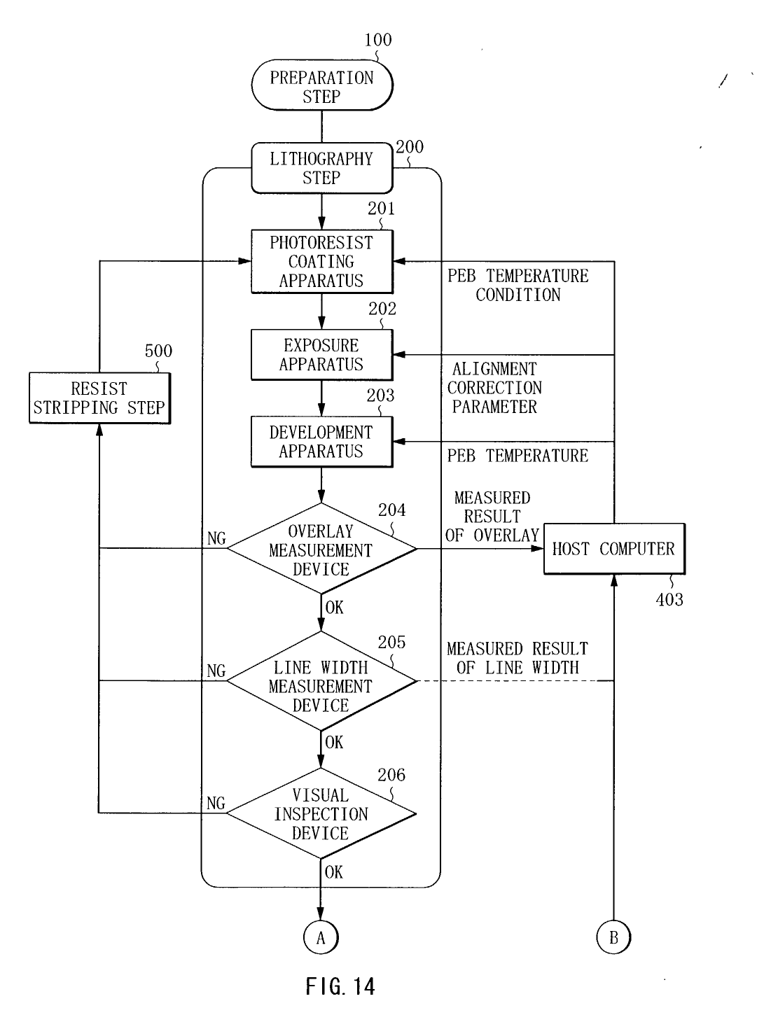

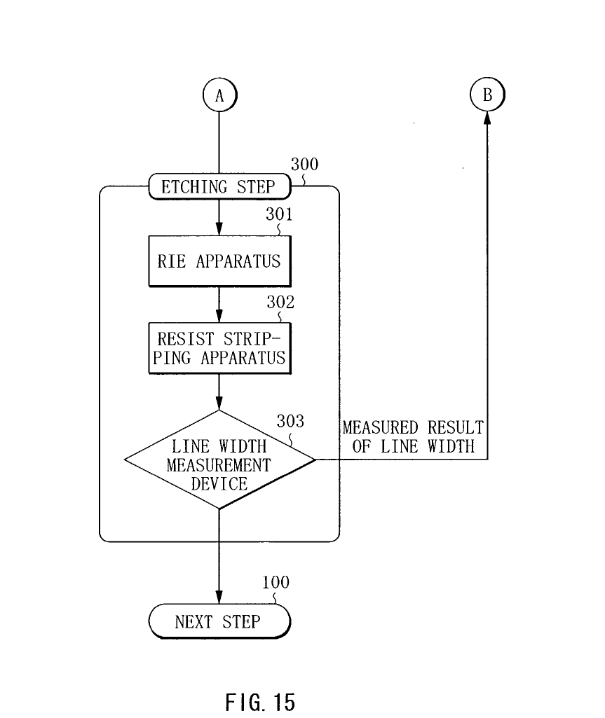

FIGS. 14 and 15 are schematic diagrams showing main fabrication apparatuses of a system for fabricating a semiconductor device according to a third embodiment of the present invention and the flow of fabrication steps carried out by these fabrication apparatuses.

According to the system for fabricating a semiconductor device in this embodiment, a host computer 403 functions as a postbake temperature adjusting apparatus in a postbake (PEB) step. The host computer 403 calculates a correction value for optimizing a postbake temperature in the postbake step so as to suppress variations in line widths on the basis of dense/sparse line width difference data obtained from values measured by a line width measurement device 205 or a line width measurement device 303, and resets an exposure amount in an exposure step carried out by an exposure apparatus 202 in the next and later lots to an optimum value.

A development apparatus 203 corrects a postbake temperature on the basis of a correction value calculated on the basis of the measured values of the line widths and the dense/sparse line width difference data for the previous lot, and carries out the postbake step at the corrected postbake temperature. The exposure apparatus 202 resets an exposure condition such as an exposure amount or an exposure time on the basis of the corrected postbake temperature. Under such a reset exposure condition, the exposure apparatus 202 will carry out the exposure step for the next lot.

According to the fabrication method and the fabrication system in the third embodiment, variations in line widths of resist patterns or patterns are suppressed by positively utilizing a function in which the postbake temperature in the postbake step exerts an effect on the occurrence of variations in line widths depending on a dense/sparse layout of the transferred resist patterns, or a function in which the postbake temperature in the postbake step also exerts an effect on the occurrence of variations in line widths depending on a dense/sparse layout of the patterns formed on a wafer by the RIE apparatus 301 in the etching step. To be more specific, a dense/sparse line width difference data regarding a correlation between a dense/sparse layout of the resist patterns or the patterns formed on the wafer and variations in line widths of the resist patterns or the patterns, are obtained from data measured by the line width measurement device 205 or the line width measurement device 303. Subsequently, on the basis of the dense/sparse line width difference data, the host computer 403 functioning as the postbake temperature adjusting apparatus calculates the optimum postbake temperature value for effectively suppressing the variations in line widths, calculates a difference between the calculated postbake temperature value and a reference prebake temperature value (initial value) as a correction value, and corrects the postbake temperature by using the correction value, whereby the variations in line widths depending on the dense/sparse line width difference are reduced or eliminated.

Variations in line widths depending on a dense/sparse line width difference may be different depending on a photo-mask used; a difference between one and another apparatus of the same kind used as the photoresist coating apparatus 201, the exposure apparatus 202, the development apparatus 203, or the RIE apparatus 301; and a combination of the apparatuses 201, 202, 203 and 301 in one line. Accordingly, variations in line widths caused in the entire fabrication system can be further reduced by further optimizing the postbake temperature in consideration of a difference between one and another apparatus and a combination of the apparatuses.

Further, in the case where a process parameter or an apparatus parameter is changed due to a modification of a fabrication process, if the change in process parameter or apparatus parameter is small enough not to require the correction of line widths from the time of designing a photo-mask, it is possible to further reset the prebake temperature in accordance with a change in parameter at that time.

### THIRD EXAMPLE

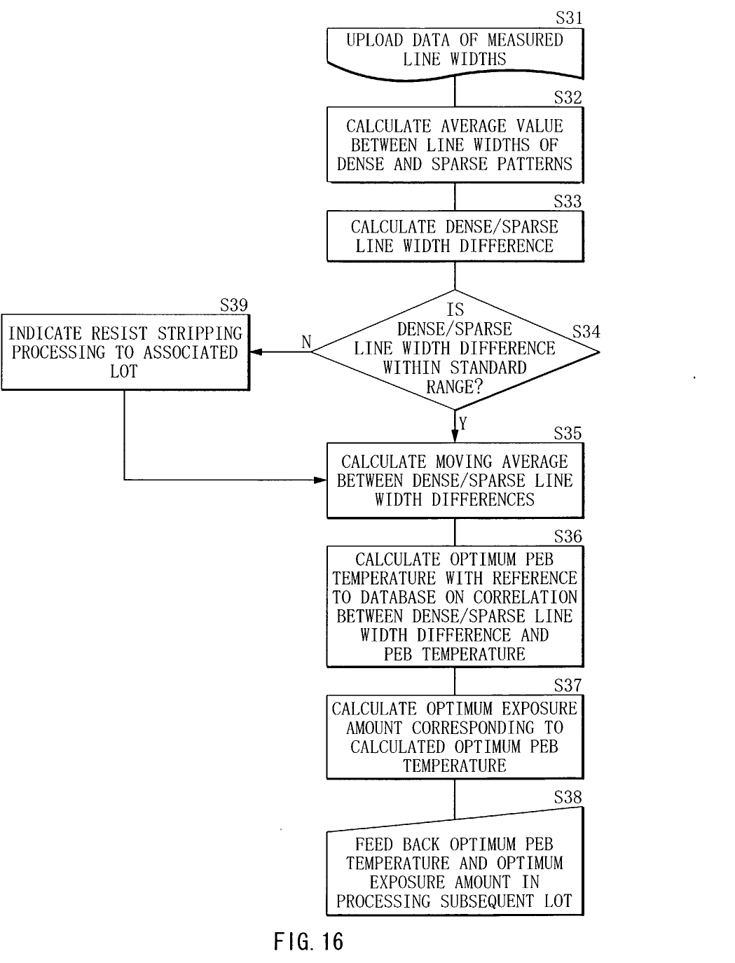

FIG. 16 is a flow diagram of main steps of a procedure for optimizing the postbake temperature in a third example.

In this third example, like the first example, the scanner type exposure apparatus including a KrF excimer laser light source (wavelength: 248 nm) was used as the exposure apparatus 202, and the PHS (Poly Hydroxy Styrene) based chemically amplified resist (produced by Tokyo Ouka Co., Ltd. under the trade name of TDUR-P509) was used as the photoresist. The photoresist was formed to a thickness of 0.46 μm.

First, as representative points at which line widths are to be measured, a plurality of points, each of which has a nearly equal ratio between a line width and an interval (line-and-space), are sampled from a pattern layout of each chip. These representative points are taken as one group, and at least one group is set in each of a sparse pattern region and a dense pattern region. Even in the third example, like the first example, in the pattern layout of the chip 10 shown in FIG. 4 on which the memory device 11 and the logic device 12 are combined, the representative points in the sparse pattern region were sampled from the pattern region of the logic device 12, and the representative points in the dense pattern region were sampled from the pattern region of the memory device 11.

First, after a photolithography step or an etching step for one product lot or a trial lot was completed, line widths of the representative points were measured, and the data were supplied to a host computer 403 functioning as a postbake temperature adjusting apparatus, to thereby upload the data of the measured values of line widths (step S31). At this time, like the first example, line widths were measured by using an electron microscope with a line width measuring function in accordance with the direct approximation method. The measured data were transmitted to the host computer 403 via a CD-SEM, an in-process local network, and the like.

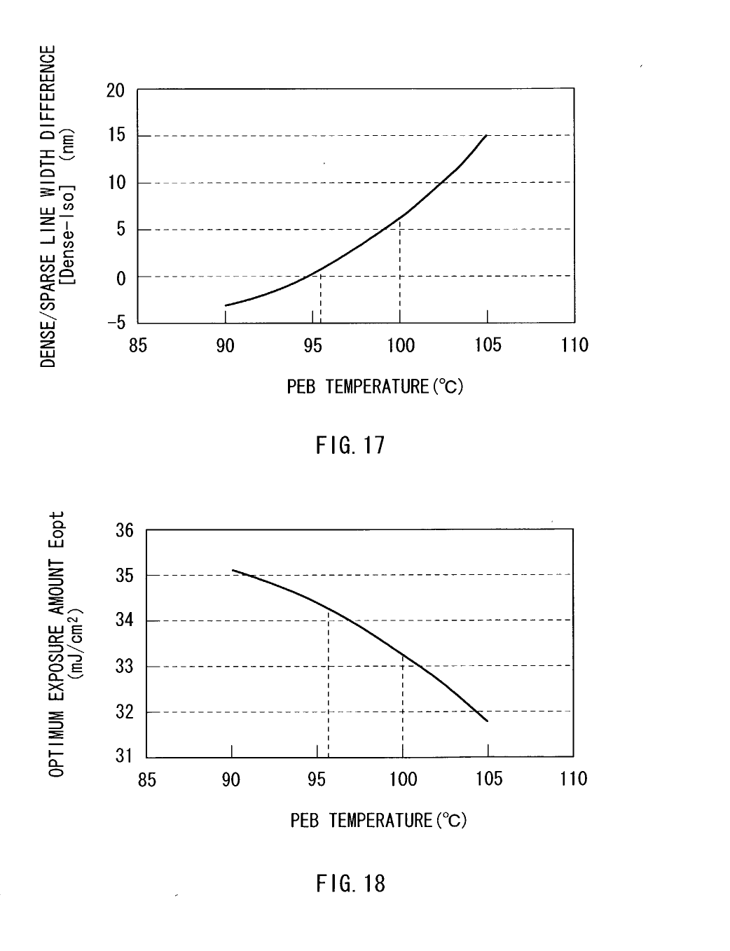

The host computer 403 calculated an average value of the measured line widths in the sparse pattern group and an average value of the measured line widths in the dense pattern group (step S32), and calculated a difference between these two averages (step S33). The value thus obtained in step S33 was taken as a dense/sparse line width difference data. A moving average value between the previous dense/sparse line width difference data, already measured and recorded in the photography step or the etching step for a past product lot or trial lot having the same patterns, and the present dense/sparse line width difference data measured for the present lot was calculated (step S35). The data obtained in step S35 was referred to pre-determined correlation data between a dense/sparse line width difference and a postbake temperature as shown in FIG. 17, and a correction value of the prebake temperature selected so as to bring the dense/sparse line width difference into zero was obtained (step S36). The exposure amount was then reset to an optimum value corresponding to the corrected postbake temperature (step S37). In addition, as typically shown in FIG. 17, a very clear linear correlation is established between the dense/sparse line width difference and the postbake temperature.

The correction value of the postbake temperature thus calculated and the reset value of the exposure amount were fed back to the exposure apparatus 202 (step S38). In the case of processing wafers of the next lot in the same steps using the same apparatuses, the data of the optimum postbake temperature thus obtained were transferred from the host computer 403 to the exposure system 202 via the in-process local network or the like, to correct the postbake temperature and reset the exposure amount.

In the above-described procedure, if the dense/sparse line width difference for the resist patterns is out of a specific range set as a control standard, that is, if the answer of step S34 is denied (NO), the wafer in the lot, on which the resist patterns have been formed, may be removed once from the product line at that time and supplied to a resist stripping (reproducing) step 500, and be coated again with the photoresist and subjected to the subsequent processing in the photolithography step (step S39). With this treatment, if the occurrence of a failure of variations in line widths for a wafer is detected in an early stage in the photolithography step, the wafer is returned to the reproducing step and then desirably patterned in the photolithography step which has been corrected so as to reduce the occurrence of variations in line widths, and accordingly, it is possible to prevent the occurrence of wasteful processing of the wafer and hence to avoid an increase in fabrication cost.

In the third example, the reference postbake temperature before correction was initially set to 100° C., and the occurrence of a dense/sparse line width difference of about 6 nm was detected. The postbake temperature was corrected to 96° C. so as to bring the dense/sparse line width difference into zero on the basis of the correlation between the postbake temperature and the dense/sparse line width difference shown in FIG. 17.

Along with the correction of the postbake temperature from 100° C. to 96° C., the optimum exposure amount was shifted to a value different from an optimum exposure amount of about 33.3 mJ/cm² corresponding to the reference postbake temperature, that is, the initial value of 100° C. To correct such a shifted value of the optimum exposure amount, on the basis of data of a correlation between the postbake temperature and an optimum exposure amount, predetermined on the basis of the data of the past product lots and experiments as shown in FIG. 18, the optimum exposure amount in the exposure apparatus 202 was reset to a value of 34.3 mJ/cm².

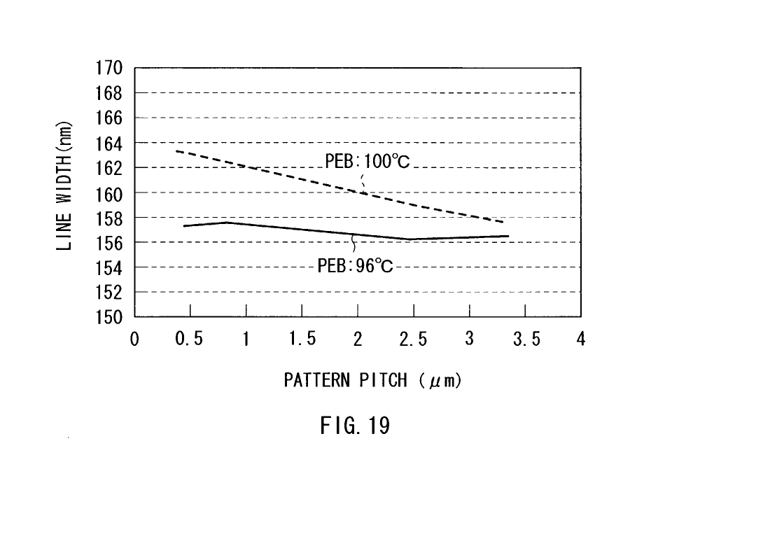

By correcting the postbake temperature from 100° C. to 96° C. and also resetting the optimum exposure amount from 33.3 mJ/cm² to 34.3 mJ/cm², a dense/sparse line width difference was corrected as shown in FIG. 19. To be more specific, as shown in FIG. 19, in a range of pattern pitches of 0.3 μm to 3.3 μm, the dense/sparse line width difference was corrected from a value of about 5.5 nm at maximum (line width range: 158 nm to 163.5 nm) to a value of about 1.5 nm or less at maximum (line width range: 156.5 nm to 158 nm). In this way, according to the third example, it was found that variations in line widths can be significantly, effectively reduced.

In the first, second and third embodiments and the first, second, and third examples, the correction of the NA, the correction of the prebake temperature, and the correction of the postbake temperature have been singly described; however, the correction of the NA, the prebake temperature, and the postbake temperature may be used in combination in a fabrication process for one lot. For example, on the basis of dense/sparse line width difference data obtained from the measured result of line widths for the previous lot, not only the NA but also the prebake temperature and the postbake temperature may be corrected.

### INDUSTRIAL APPLICABILITY

With the configurations of the method of or system for fabricating a semiconductor device according to the present invention, since variations in line widths of patterns formed by a plurality of steps are reduced by adjusting a processing condition of a specific one of the plurality of steps on the basis of a correlation between the variations in line widths and a dense/sparse line layout for the patterns, it is possible to suppress the variations in line widths due to a dependence of the dense/sparse line layout on the line widths, and hence to highly accurately form micro-patterns.

With the configurations of the method of or system for fabricating a semiconductor device according to an aspect of the present invention, since variations in line widths of patterns formed in the patterning step or variations in line widths of resist patterns formed in the photolithography step are reduced by adjusting the numerical aperture of an optical system on the basis of a correlation between the variations in line widths and a dense/sparse line layout for the patterns or a correlation between the variations in line widths and a dense/sparse line layout for the resist patterns, it is possible to suppress the variations in line widths due to a dependence of the dense/sparse line layout on the line widths, and hence to highly accurately form micro-patterns.

With the configurations of the method of or system for fabricating a semiconductor device according to another aspect of the present invention, since variations in line widths of resist patterns formed in the photolithography step are reduced by adjusting the prebake temperature in the prebake step on the basis of a correlation between the variations in line widths and a dense/sparse line layout for the resist patterns, it is possible to suppress the variations in line widths due to a dependence of the dense/sparse line layout on the line widths, and hence to highly accurately form micro-patterns.

With the configurations of the method of or the system for fabricating a semiconductor device according to a still another aspect of the present invention, since variations in line widths of resist patterns formed in the postbake step are reduced by adjusting the postbake temperature in the postbake step on the basis of a correlation between the variations in line widths and a dense/sparse line layout for the patterns formed in the patterning step, it is possible to suppress the variations in line widths due to a dependence of the dense/sparse line layout on the line widths, and hence to highly accurately form micro-patterns.

Obviously many modifications and variations of the present invention are possible in the light of the above teachings. It is therefore to be understood that within the scope of the appended claims the invention may be practiced otherwise than as specifically described.

1. A method of fabricating a semiconductor device, comprising:
a plurality of steps of forming patterns on a wafer by adjusting processing conditions;
wherein the processing condition of a specific one of said plurality of steps is adjusted so as to reduce variations in line widths of said patterns formed in said plurality of steps on the basis of a correlation between the variations in line widths and a dense/sparse line layout for said patterns.

2. A method of fabricating a semiconductor device, comprising:
a photolithography step of transferring a mask pattern to a photoresist on a wafer by adjusting a numerical aperture of an optical system of an exposure apparatus, to form resist patterns; and
a patterning step of forming patterns on said wafer on the basis of said resist patterns;
wherein the numerical aperture of said optical system is adjusted so as to reduce variations in line widths of said patterns formed in said patterning step or variations in line widths of said resist patterns formed in said photolithography step on the basis of a correlation between the variations in line widths and a dense/sparse line layout for said patterns or a correlation between the variations in line widths and a dense/sparse line layout for said resist patterns.

3. A method of fabricating a semiconductor device according to claim 2, further comprising:
a step of correcting said mask pattern on the basis of a previously quantified correction value in accordance with said correlation between the variations in line widths and a dense/sparse line layout for said patterns.

4. A method of fabricating a semiconductor device according to claim 3, wherein in order to determine said correlation between the variations in line widths and a dense/sparse line layout for said patterns or said resist patterns, line widths of patterns or resist patterns positioned at a plurality of predetermined points as representative points on said wafer are measured, and information on a correlation between variations in line widths and a dense/sparse line layout for said patterns or and resist patterns is obtained from the measured result;
a correction value of a predetermined numerical aperture is determined so as to reduce said variations in line widths of said patterns or said resist patterns in accordance with said information on the correlation; and
the numerical aperture of said optical system is adjusted on the basis of said correction value.

5. A method of fabricating a semiconductor device according to claim 4, wherein as said representative points, a plurality of points are set in each of a sparse pattern group or a sparse resist pattern group and a dense pattern group or a dense resist pattern group;
an average value of line widths measured in each group is calculated; and
a correction value of said numerical value is determined by using a difference between the average values as said information on the correlation between the variations in line widths and a dense/sparse line layout for said patterns or said resist patterns.

6. A method of fabricating a semiconductor device according to claim 4, further comprising:
a step of setting an optimum exposure amount corresponding to said corrected numerical aperture on the basis of information on a correlation between said numerical aperture and said optimum exposure amount in said photolithography step.

7. A method of fabricating a semiconductor device, comprising:
a prebake step of coating a photoresist on a wafer and pre-baking the photoresist while adjusting a prebake temperature; and
a photolithography step of transferring a mask pattern to the photoresist, to form resist patterns;
wherein said prebake temperature is adjusted so as to reduce variations in line widths of said resist patterns formed in said photolithography step on the basis of a correlation between the variations in line widths and a dense/sparse line layout for said resist patterns.

8. A method of fabricating a semiconductor device according to claim 7, further comprising:
a step of correcting said prebake temperature on the basis of a previously quantified correction value in accordance with said correlation between the variations in line widths and a dense/sparse line layout for said resist patterns.

9. A method of fabricating a semiconductor device according to claim 8, wherein in order to determine said correlation between the variations in line widths and a dense/sparse line layout for said resist patterns, line widths of resist patterns positioned at a plurality of predetermined points as representative points on said wafer are measured, and information on a correlation between variations in line widths and a dense/sparse line layout for said resist patterns is obtained from the measured result;
a correction value of a predetermined prebake temperature is determined so as to reduce said variations in line widths of said resist patterns in accordance with said information on the correlation; and
said prebake temperature is adjusted on the basis of said correction value.

10. A method of fabricating a semiconductor device according to claim 9, wherein as said representative points, a plurality of points are set in each of a sparse resist pattern group and a dense resist pattern group;
an average value of line widths measured in each group is calculated; and
a correction value of said prebake temperature is determined by using a difference between the average values as said information on the correlation between the variations in line widths and a dense/sparse line layout for the resist patterns.

11. A method of fabricating a semiconductor device according to claim 9, further comprising:
a step of setting an optimum exposure amount corresponding to said corrected prebake temperature on the basis of information on a correlation between said prebake temperature and said optimum exposure amount in said photolithography step.

12. A method of fabricating a semiconductor device according to claim 7, wherein a chemically amplified resist containing an acid generating agent capable of generating an acid by an optical reaction is used as said photoresist.

13. A method of fabricating a semiconductor device, comprising:
a postbake step of post-baking resist patterns, which have been formed on a wafer by processing a photoresist, while adjusting a postbake temperature; and
a patterning step of forming patterns on said wafer on the basis of said resist patterns;
wherein said postbake temperature is adjusted so as to reduce variations in line widths of said resist patterns on the basis of a correlation between the variations in line widths and a dense/sparse line layout for said resist patterns.

14. A method of fabricating a semiconductor device according to claim 13, further comprising:
a step of correcting said postbake temperature on the basis of a previously quantified correction value in accordance with said correlation between the variations in line widths and a dense/sparse line layout for said resist patterns.

15. A method of fabricating a semiconductor device according to claim 14, wherein in order to determine said correlation between the variations in line widths and a dense/sparse line layout for said resist patterns, line widths of resist patterns positioned at a plurality of predetermined points as representative points on said wafer are measured, and information on a correlation between variations in line widths and a dense/sparse line layout for said resist patterns is obtained from the measured result;
a correction value of a predetermined postbake temperature is determined so as to reduce said variations in line widths of said resist patterns in accordance with said information on the correlation; and
said postbake temperature is adjusted on the basis of said correction value.

16. A method of fabricating a semiconductor device according to claim 15, wherein as said representative points, a plurality of points are set in each of a sparse resist pattern group and a dense resist pattern group;
an average value of line widths measured in each group is calculated; and
a correction value of said postbake temperature is determined by using a difference between the average values as said information on the correlation between the variations in line widths and a dense/sparse line layout for said resist patterns.

17. A method of fabricating a semiconductor device according to claim 15, further comprising:
a step of setting an optimum exposure amount corresponding to said corrected postbake temperature on the basis of information on a correlation between said postbake temperature and said optimum exposure amount in a photolithography step for forming said resist patterns.

18. A method of fabricating a semiconductor device according to claim 13, wherein a chemically amplified resist containing an acid generating agent capable of generating an acid by an optical reaction is used as said photoresist.

19. A system for fabricating a semiconductor device, which is used for carrying out a plurality of steps of forming patterns on a wafer by adjusting processing conditions, said system comprising:
means for adjusting the processing condition of a specific one of said plurality of steps so as to reduce variations in line widths of said patterns formed in said plurality of steps on the basis of a correlation between the variations in line widths and a dense/sparse line layout for said patterns.

20. A system for fabricating a semiconductor device, comprising:
a photolithography apparatus for transferring a mask pattern to a photoresist on a wafer by adjusting a numerical aperture of an optical system, to form resist patterns;
a patterning apparatus for forming patterns on said wafer on the basis of said resist patterns; and
a numerical aperture adjusting apparatus for adjusting the numerical aperture of said optical system so as to reduce variations in line widths of said patterns formed by said patterning apparatus or variations in line widths of said resist patterns formed by said photolithography apparatus on the basis of a correlation between the variations in line widths and a dense/sparse line layout for said patterns or a correlation between the variations in line widths and a dense/sparse line layout for said resist patterns.

21. A system for fabricating a semiconductor device according to claim 20, wherein in order to determine said correlation between the variations in line widths and a dense/sparse line layout for said patterns or said resist patterns, said numerical aperture adjusting apparatus measures line widths of patterns or resist patterns positioned at a plurality of predetermined points as representative points on said wafer, and obtains, from the measured result, information on a correlation between variations in line widths and a dense/sparse line layout for said patterns or said resist patterns; and
said numerical aperture adjusting apparatus determines a correction value of a predetermined numerical aperture so as to reduce said variations in line widths of said patterns or said resist patterns in accordance with said information on the correlation, and adjusts the numerical aperture of said optical system on the basis of said correction value.

22. A system for fabricating a semiconductor device according to claim 21, wherein said numerical aperture adjusting apparatus sets a plurality of points as said representative points in each of a sparse pattern group or a sparse resist pattern group and a dense pattern group or a dense resist pattern group, calculates an average value of line widths measured in each group, and determines a correction value of said numerical value by using a difference between the average values as said information on the correlation between the variations in line widths and a dense/sparse line layout for said patterns or said resist patterns.

23. A system for fabricating a semiconductor device according to claim 21, wherein said numerical aperture adjusting apparatus sets an optimum exposure amount corresponding to said corrected numerical aperture on the basis of information on a correlation between said numerical aperture and said optimum exposure amount used in said photolithography apparatus.

24. A system for fabricating a semiconductor device, comprising:
a pre-baking apparatus for pre-baking a photoresist on a wafer while adjusting a prebake temperature;
a photolithography apparatus of transferring a mask pattern to the photoresist, to form resist patterns; and
a prebake temperature adjusting apparatus for adjusting said prebake temperature so as to reduce variations in line widths of said resist patterns formed by said photolithography apparatus on the basis of a correlation between the variations in line widths and a dense/sparse line layout for said resist patterns.

25. A system for fabricating a semiconductor device according to claim 24, wherein said prebake temperature adjusting apparatus corrects said prebake temperature on the basis of a previously quantified correction value in accordance with said correlation between the variations in line widths and a dense/sparse line layout for said resist patterns.

26. A system for fabricating a semiconductor device according to claim 24, wherein in order to determine said correlation between the variations in line widths and a dense/sparse line layout for said resist patterns, said prebake temperature apparatus measures line widths of resist patterns positioned at a plurality of predetermined points as representative points on said wafer, and obtains, from the measured result, information on a correlation between variations in line widths and a dense/sparse line layout for said resist patterns; and
said prebake temperature adjusting apparatus determines a correction value of a predetermined prebake temperature so as to reduce said variations in line widths of said resist patterns in accordance with said information on the correlation, and adjusts said prebake temperature on the basis of said correction value.

27. A system for fabricating a semiconductor device according to claim 26, wherein said prebake temperature adjusting apparatus sets a plurality of points as said representative points in each of a sparse resist pattern group and a dense resist pattern group, calculates an average value of line widths measured in each group, and determines a correction value of said prebake temperature by using a difference between the average values as said information on the correlation between the variations in line widths and a dense/sparse line layout for said resist patterns.

28. A system for fabricating a semiconductor device according to claim 24, wherein said prebake temperature adjusting apparatus sets an optimum exposure amount corresponding to said corrected prebake temperature on the basis of information on a correlation between said prebake temperature and said optimum exposure amount used for said photolithography apparatus.

29. A system for fabricating a semiconductor device, comprising:
a post-baking apparatus for post-baking resist patterns, which have been formed on a wafer by processing a photoresist, while adjusting a postbake temperature;
a patterning apparatus for forming patterns on said wafer on the basis of said resist patterns; and
a postbake temperature adjusting apparatus for adjusting said postbake temperature so as to reduce variations in line widths of said resist patterns on the basis of a correlation between the variations in line widths and a dense/sparse line layout for said resist patterns.

30. A system for fabricating a semiconductor device according to claim 29, wherein said postbake temperature adjusting apparatus corrects said postbake temperature on the basis of a previously quantified correction value in accordance with said correlation between the variations in line widths and a dense/sparse line layout for said resist patterns.

31. A system for fabricating a semiconductor device according to claim 30, wherein in order to determine said correlation between the variations in line widths and a dense/sparse line layout for said resist patterns, said postbake temperature adjusting apparatus measures line widths of resist patterns positioned at a plurality of predetermined points as representative points on said wafer, and to obtains, from the measured result, information on a correlation between variations in line widths and a dense/sparse line layout for said resist patterns; and
said postbake temperature adjusting apparatus determines a correction value of a predetermined postbake temperature so as to reduce said variations in line widths of said resist patterns in accordance with said information on the correlation, and adjusts said postbake temperature on the basis of said correction value.

32. A system for fabricating a semiconductor device according to claim 31, wherein said postbake temperature adjusting apparatus sets a plurality of points as said representative points in each of a sparse resist pattern group and a dense resist pattern group, calculates an average value of line widths measured in each group, and determines a correction value of said postbake temperature by using a difference between the average values as said information on the correlation between the variations in line widths and a dense/sparse line layout for said resist patterns.

33. A system for fabricating a semiconductor device according to claim 31, wherein said postbake temperature adjusting apparatus sets an optimum exposure amount corresponding to said corrected postbake temperature on the basis of information on a correlation between said postbake temperature and said optimum exposure amount used in a photolithography apparatus for forming said resist patterns.

34. A system for fabricating a semiconductor device according to claim 29, wherein a chemically amplified resist containing an acid generating agent capable of generating an acid by an optical reaction is used as said photoresist.
